(19) United States
(12) Patent Application Publication
(10) Pub. No.: US 2009/0286387 A1
(43) Pub. Date: Nov. 19, 2009

(54) Modulation of Tantalum-Based Electrode Workfunction

(76) Inventors: David C. Gilmer, Austin, TX (US); Srikanth B. Samavedam, Austin, TX (US); James K. Schaeffer, Austin, TX (US); Voon-Yew Thean, Austin, TX (US)

Correspondence Address: HAMILTON & TERRILE, LLP - FREESCALE, P.O. BOX 203518, AUSTIN, TX, 78720, US

(21) Appl. No.: 12/122,178

(22) Filed: May 16, 2008

(51) Int. Cl. H01L 21/28; H01L 21/4763; H01L 21/3205

(52) U.S. Cl. 438/592; 257/E21.177

(57) ABSTRACT

A semiconductor process and apparatus fabricate a metal gate electrode by forming a first conductive layer (14) over a gate dielectric layer (12) and then selectively introducing nitrogen into the portions of the first conductive layer (14) in the PMOS device region (1), either by annealing (42) a nitrogen-containing diffusion layer (22) formed in the PMOS device region (1) or by performing an ammonia anneal process (82) while the NMOS device region (2) is masked. By introducing nitrogen into the first conductive layer (14), the work function is modulated toward PMOS band edge.

### BACKGROUND OF THE INVENTION

1. Field of the Invention

The present invention is directed in general to the field of semiconductor devices. In one aspect, the present invention relates to the fabrication of metal gate electrodes used in semiconductor devices.

2. Description of the Related Art

As the size and scaling of semiconductor device technology is reduced, aspects of device design and fabrication that previously gave rise to only second-order effects in long-channel devices can no longer be ignored. For example, the reduced scaling of channel length and gate oxide thickness in a conventional MOS transistor exacerbates problems of polysilicon gate depletion, high gate resistance, high gate tunneling leakage current and dopant (i.e., boron) penetration into the channel region of the device. As a result, CMOS technology is increasingly replacing silicon dioxide gate dielectrics and polysilicon gate conductors with high dielectric constant (high-k) dielectrics in combination with metal gate electrodes formed from a gate stack of polysilicon and one or more metal layers. With such technologies, the metal gate layers not only obviate gate-depletion and boron-penetration effects, but also provide a significantly lower sheet resistance.

While high-k dielectrics in conjunction with metal gate electrodes advantageously exhibit improved transistor performance, the use of new metal layer technologies can create new technical challenges. For example, to optimize drain current and device performance and reduce the voltage threshold Vts, the desired effective work function for NMOS and PMOS gate electrodes must be near the conduction (valence) band edge of silicon, meaning that the metals used in NMOS transistors should have effective work functions near 4.1 eV and metals used in PMOS transistors should have effective work functions near 5.2 eV. Since it is difficult to find a material that can have its work function adjusted once it is deposited, conventional approaches for obtaining differentiated work functions have involved forming separate gate electrode layers, such as by removing a deposited first metal gate layer from the gate insulator to deposit a second metal gate layer having a different work function. Such processes can damage the gate insulator layer, leading to high leakage or reliability problems for the finally formed device.

Accordingly, a need exists for an improved poly/metal gate electrode and manufacture method for manufacturing NMOS and PMOS devices having the work functions that are set near the silicon band edges for low voltage thresholds and improved device performance. There is also a need for a controlled fabrication process that reliably produces thermally stable metal gate electrodes without damaging the gate insulator layer. In addition, there is a need for improved semiconductor device structure and manufacturing process to overcome the problems in the art, such as outlined above. Further limitations and disadvantages of conventional processes and technologies will become apparent to one of skill in the art after reviewing the remainder of the present application with reference to the drawings and detailed description which follow.

### BRIEF DESCRIPTION OF THE DRAWINGS

The present invention may be understood, and its numerous objects, features and advantages obtained, when the following detailed description is considered in conjunction with the following drawings, in which:

FIG. 1 is a partial cross-sectional view of a semiconductor structure including a substrate, a gate dielectric layer and a first work function-setting metal layer;

FIG. 2 illustrates processing subsequent to FIG. 1 after one or more nitrogen diffusion layers are formed on the first work function-setting metal layer;

FIG. 3 illustrates processing subsequent to FIG. 2 after the nitrogen diffusion layers are selectively removed from the NMOS device region(s);

FIG. 4 illustrates processing subsequent to FIG. 3 while the nitrogen diffusion layers are heated to diffuse nitrogen into the first work function-setting metal layer formed in the PMOS device region(s);

FIG. 5 illustrates processing subsequent to FIG. 4 after removal of the nitrogen diffusion layers;

FIG. 6 illustrates processing subsequent to FIG. 1 in accordance with alternate embodiments after a masking layer is deposited on the first work function-setting metal layer and selectively masked with a patterned photoresist layer formed over the NMOS device region(s);

FIG. 7 illustrates processing subsequent to FIG. 6 after the exposed masking layer is removed;

FIG. 8 illustrates processing subsequent to FIG. 7 after an anneal in a nitrogen-containing ambient is performed to introduce nitrogen into the first work function-setting metal layer in the PMOS device region(s), while the masking layer blocks the incorporation of nitrogen into the work function setting layer in the NMOS device region(s);

FIG. 9 illustrates processing subsequent to FIG. 8 after removal of the masking layer;

FIG. 10 illustrates processing subsequent to FIGS. 5 or 9 after a silicon-containing cap layer and an ARC layer are deposited over the semiconductor structure;

FIG. 11 illustrates processing subsequent to FIG. 10 after the silicon-containing cap layer and underlying work function-setting metal layers are selectively etched to form gate electrodes;

FIG. 12 illustrates processing subsequent to FIG. 11 after source/drain regions are formed around the gate electrode structures and/or one or more sidewall spacers;

FIG. 13 graphically represents the device performance benefits provided in accordance with selected embodiments of the present invention where a nitrogen-containing layer is used as a solid state diffusion source; and

FIG. 14 graphically represents the device performance benefits provided in accordance with selected embodiments of the present invention where a nitrogen anneal process is used.

It will be appreciated that for simplicity and clarity of illustration, elements illustrated in the drawings have not necessarily been drawn to scale. For example, the dimensions of some of the elements are exaggerated relative to other elements for purposes of promoting and improving clarity and understanding. Further, where considered appropriate, reference numerals have been repeated among the drawings to represent corresponding or analogous elements.

### DETAILED DESCRIPTION

A metal gate electrode and its method of manufacture are described in which a metal layer is deposited and the work function is selectively modulated or adjusted by selectively introducing nitrogen into the metal layer over regions where predetermined device types (e.g., PMOS devices) are formed. In selected embodiments, metal-based electrodes are formed by depositing a metal-based electrode layer (e.g., TiC, TaC, HfC, TaSi, ZrC, Hf, etc.) over a gate dielectric layer, where the metal-based electrode layer has a work function that is suitable for an NMOS transistor. In the PMOS device areas, the work function of the deposited metal-based electrode layer is then modulated toward the PMOS band edge by selectively introducing nitrogen into the metal-based electrode layer. Nitrogen may be introduced using a nitrogen diffusion source, such as by depositing a layer of nitrogen-containing metal (e.g., Mo₂N, MoAlN, RuₓN_{y}, W₂N, etc.) onto the metal-based electrode layer and the heating or annealing the wafer sufficiently to drive nitrogen from the nitrogen-containing metal and into the metal-based electrode layer, thereby increasing the work function of the metal-based electrode layer. By removing the nitrogen-containing metal layer from the NMOS device areas before the heating/annealing process occurs, the original work function of the deposited metal-based electrode layer remains unchanged over the NMOS device areas, thereby allowing differentiated work functions to be obtained for PMOS and NMOS devices. In addition, by removing the nitrogen-containing metal layer after the heating/annealing step, the subsequent CMOS gate etch process may be applied equally to the NMOS and PMOS devices. As will be appreciated, other techniques may be used to incorporate or introduce nitrogen into the metal-based electrode layer over the PMOS region to increase the layer's work function, such as by annealing the wafer in nitrogen or by exposing the metal-based electrode layer to nitrogen atom or radicals using a nitrogen plasma or implant process. With the approaches described herein, a single metal-based gate electrode layer is used to selectively adjust the work function so that the NMOS and PMOS devices have the desired effective work functions.

Various illustrative embodiments of the present invention will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are depicted with reference to simplified cross sectional drawings of a semiconductor device without including every device feature or geometry in order to avoid limiting or obscuring the present invention. Such descriptions and representations are used by those skilled in the art to describe and convey the substance of their work to others skilled in the art.

Turning now to FIG. 1, a partial cross-sectional view is depicted of a semiconductor structure 10, including a substrate 11, a gate dielectric layer 12 and a first work function-setting metal layer 14. Depending on the type of device being fabricated, the substrate 11 may be implemented as a bulk silicon substrate, single crystalline silicon (doped or undoped), or any semiconductor material including, for example, Si, SiC, SiGe, SiGeC, Ge, GaAs, InAs, InP as well as other Group III-IV compound semiconductors or any combination thereof, and may optionally be formed as the bulk handling wafer. In addition, the substrate 11 may be implemented as the top silicon layer of a semiconductor-on-insulator (SOI) structure or three sides of a semiconductor slab which may be used to form the active region of a surround-gate or tri-gate device, such as a FinFET device. Though not illustrated, one or more isolation regions and/or well regions may be formed in the substrate 11 to define one or more active regions over which the transistor devices are formed, such as by using a twin well process in which first well is selectively implanted into portions of substrate 11 where devices of a first conductivity type will be formed while a second well is selectively implanted into regions of substrate 11 into which transistors of a second different and opposite conductivity type will be formed. Prior to forming the metal layer 14, an insulator or dielectric layer 12 is formed by depositing or growing an insulator or high-k dielectric (e.g., silicon dioxide, oxynitride, metal-oxide, nitride, etc.) over the semiconductor substrate 11 using chemical vapor deposition (CVD), plasma-enhanced chemical vapor deposition (PECVD), physical vapor deposition (PVD), atomic layer deposition (ALD), thermal oxidation, or any combination(s) of the above. In an illustrative implementation, first dielectric layer 12 is a metal-oxide compound formed by chemical vapor deposition, physical vapor deposition, or by atomic layer deposition having a typical final thickness is in the range of 0.1-10 nanometers, though other thicknesses may be used. A suitable metal oxide compound for use as first dielectric layer 12 is hafnium oxide (preferably HfO₂), though other oxides, silicates or aluminates of zirconium, aluminum, lanthanum, strontium, tantalum, titanium and combinations thereof may also be used, including but not limited to Ta₂O₅, ZrO₂, HfO₂, TiO₂, Al₂O₃, Y₂O₃, La₂O₃, HfSiOₓ, ZrSiOₓ, ZrHfOx, LaSiOₓ, YSiOₓ, ScSiOₓ, CeSiOₓ, HfLaSiOₓ, HfAlOₓ, ZrAlOₓ, and LaAlOₓ. In addition, multi-metallic oxides (for example barium strontium titanate, BST) may also provide high-k dielectric properties.

After forming the first dielectric layer 12, a first work function-setting metal or metal-based layer 14 is formed using any desired deposition or sputtering process, such as CVD, PECVD, PVD, ALD, molecular beam deposition (MBD) or any combination(s) thereof. The first metal-based layer 14 includes an element selected from the group consisting of Ti, Ta, Ir, Mo, Ru, W, Os, Nb, Ti, V, Ni, and Re. In selected embodiments, the first metal-based layer 14 is formed with a metal or metal-based layer that has a work function that is suitable for an NMOS transistor. For example, the metal-based gate layer 14 may be formed over the first dielectric layer 12 using an atomic layer deposition (ALD) process that forms a TaC layer having a thickness of less than 20-100 Angstroms, though other metallic gate layer materials (such as HfC, TaSi, ZrC, Hf, etc.) or even a conductive metal oxide (such as IrO₂) with different thicknesses, may be used. An example process for depositing a thin TaC layer 14 uses a physical vapor deposition (PVD) process to reactively sputter TaC from a Ta target in an Ar, CxHy ambient, though an ALD process could be used to selectively form a thin TaC layer 14 on the surface of the semiconductor structure 10 by applying a TaF₅ pulse (or some other tantalum-containing precursor, such as tantalum halide or tantalum metal organic), then purging with argon, then pulsing with plasma (e.g., CxHy) and then purging with argon again. This sequence of steps may be repeated until the desired thickness of TaC is obtained on the semiconductor structure 10. The foregoing sequence of steps may be used to form a single metal-based layer 14 over both the PMOS transistor device regions 1 and the NMOS transistor device regions 2. However, as described hereinbelow, the portions of the metal-based layer 14 over the PMOS transistor device regions 1 will be processed to introduce and incorporate nitrogen into the PMOS portions of the metal-based layer 14, thereby adjusting its work function to be close to the valence band of the silicon substrate. As will be appreciated, the first work function-setting metal or metal-based layer 14 may be formed from one or more layers. For example, the metal-based gate layer 14 may be formed over the first dielectric layer 12 by first forming a layer of TaMgC to a thickness of approximately 2.5 Angstroms, followed by the formation of a layer of TaC to a thickness of approximately 90 Angstroms. Since the thin TaMgC layer adjusts the work function of the TaC layer to match the ideal NMOS threshold voltage, the combined TaMgC/TaC layers over the NMOS regions 2 may be shielded from nitrogen processing described herein and used to form the NMOS metal gates. Of course, by starting with a combination TaMgC/TaC layer, the threshold voltage of the combined layers must be shifted even further for PMOS devices, which may be done by forming a channel SiGe layer and/or by incorporating additional nitrogen into the metal-based gate layer 14 as described herein.

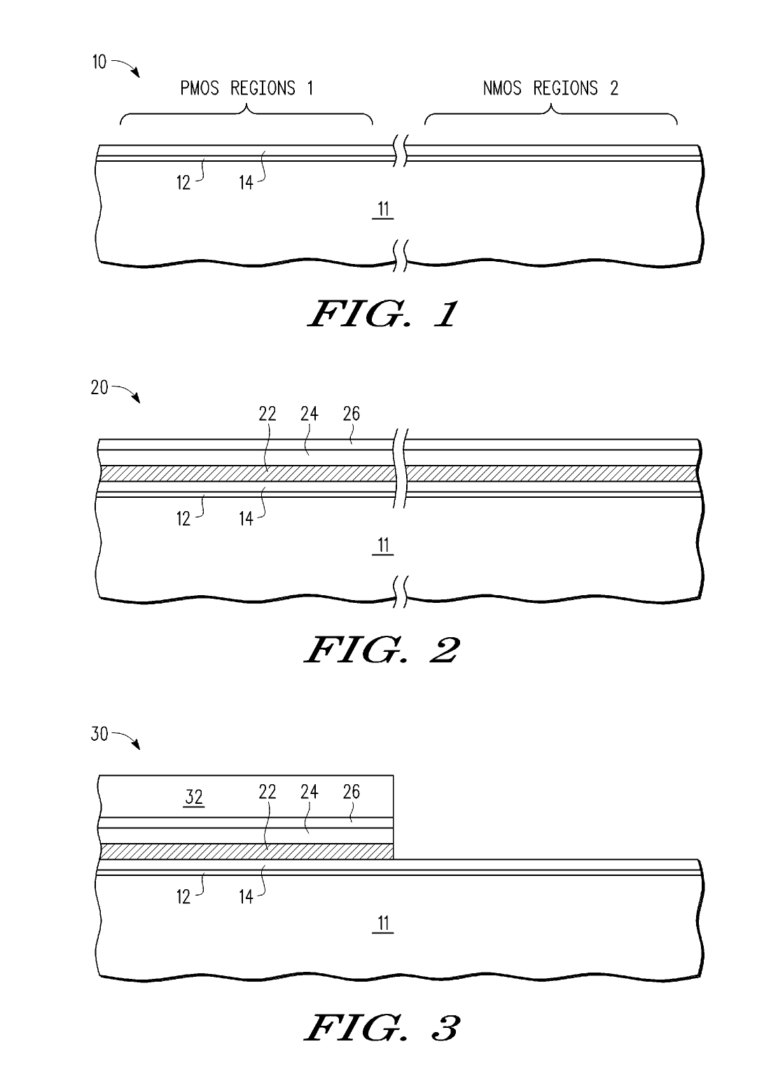

To illustrate an example technique for introducing nitrogen into the metal-based layer 14, reference is now made to FIG. 2 which depicts processing of the semiconductor structure 20 subsequent to FIG. 1 after one or more nitrogen diffusion layers (e.g., 22, 24, 26) are formed on the first work function-setting metal layer 14. After depositing the first metal layer 14, a nitrogen diffusion source layer 22 is formed on the first work function-setting metal layer 14 using any desired deposition or sputtering process, such as CVD, PECVD, PVD, ALD, molecular beam deposition (MBD) or any combination(s) thereof. The nitrogen diffusion layer 22 includes a nitrogen-containing material formed by combining nitrogen with an element selected from the group consisting of Ta, Ir, Mo, Ru, W, Os, Nb, Ti, V, Ni, and Re. In a selected embodiment, the nitrogen diffusion source layer 22 is formed by depositing a molybdenum metal layer which contains nitrogen, such as Mo₂N, having a thickness of between 50 and 150 Angstroms, and more particularly approximately 100 Angstroms, though other nitrogen-containing materials (such as MoAlN, RuₓN_{y}, W₂N, etc.) with different thicknesses may be used. As will be appreciated, the nitrogen diffusion layer 22 may be formed directly on the first work function-setting metal layer 14 without any intervening layers.

To cap the nitrogen diffusion source layer 22 and prevent nitrogen from escaping during subsequent heat treatment, a first nitride layer 24 is formed on the nitrogen diffusion source layer 22 using any desired deposition or sputtering process, such as CVD, PECVD, PVD, ALD, molecular beam deposition (MBD) or any combination(s) thereof In a selected embodiment, the first nitride layer 24 is formed by depositing a layer of titanium nitride having a thickness of between 50 and 100 Angstroms, and more particularly approximately 70 Angstroms, though other nitride materials with different thicknesses may be used. In addition, a second nitride cap layer 26 may be formed using any desired deposition or sputtering process, such as CVD, PECVD, PVD, ALD, molecular beam deposition (MBD) or any combination(s) thereof. In a selected embodiment, the second nitride layer 26 is formed by depositing a layer of silicon nitride having a thickness of between 50 and 150 Angstroms, and more particularly approximately 100 Angstroms, though other nitride materials with different thicknesses may be used.

As will be appreciated, by heating or annealing the semiconductor structure 20, the nitrogen diffusion layer 22 may be used to diffuse nitrogen into the entirety of the first work function-setting metal layer 14, thereby increasing the work function for the entire layer 14. However, the work function adjustment may be selectively applied to the first work function-setting metal layer 14 by removing the nitrogen diffusion source layer 22 from those regions where a work function adjustment is not desired. To this end, FIG. 3 illustrates processing of the semiconductor structure 30 subsequent to FIG. 2 after portion(s) of the nitrogen diffusion layers 22 are selectively removed from the NMOS device region(s) 2. In particular, selected portions of the nitrogen diffusion layers 22, first nitride layer 24, and second nitride cap layer 26 have been removed by applying and patterning a layer of photoresist or other masking layer(s) to form a patterned mask layer 32. Using the patterned mask layer 32, the exposed portions of the nitrogen diffusion layers 22, first nitride layer 24, and second nitride cap layer 26 are selectively etched and removed from the NMOS region 2, thereby leaving portions of the nitrogen diffusion layers 22, first nitride layer 24, and second nitride cap layer 26 in the PMOS region 1. The pattern transfer and etching of the mask layer may use one or more etching steps to selectively remove the unprotected portions of the layers 22, 24, 26, including a dry etching process such as reactive-ion etching, ion beam etching, plasma etching or laser etching, a wet etching process wherein a chemical etchant is employed or any combination thereof. Though not shown in FIG. 3, it will be appreciated that the PMOS region(s) 1 and NMOS region(s) 2 may be separated from one another by an isolation insulator or dielectric layer, such as a shallow trench isolation region, which electrically insulates the PMOS and NMOS regions in the substrate 11 from one another.

Once the nitrogen diffusion layer 22 is removed from regions where the work function adjustment is not to desired, a thermal budget may be applied to induce a reaction which allows for nitrogen to move from the remaining nitrogen diffusion layer 22 and into the first work function-setting metal layer 14 so as to increase its work function. This is shown in FIG. 4 which depicts processing of the semiconductor structure 40 subsequent to FIG. 3 while the nitrogen diffusion layers (e.g., 22) are heated (as indicated by the heat wave lines 42) to diffuse nitrogen into the first work function-setting metal layer 44 formed in the PMOS device region 1. At this stage, the heating process drives or diffuses the nitrogen into the first work function-setting metal layer to form the nitrogen-doped metal layer 44 having an adjusted work function. In contrast, the work function-setting metal layer 46 formed in the NMOS device region 1 does not absorb nitrogen from the nitrogen diffusion layers (e.g., 22), and thereby retains its original work function. In one embodiment, the time, temperature and other conditions for the anneal process are selected to optimize the incorporation of nitrogen into the underlying metal layer for purposes of increasing its work function, such as by using an rapid thermal anneal process which heats the semiconductor device 40 with a temperature ramp up (e.g., 50 degrees per second) to a target temperature of between approximately 800 and 1100 degrees Celsius where the temperature is maintained for 5-40 seconds (e.g., a spike anneal drive process), followed by a rapid temperature ramp down. Alternately, the nitrogen diffusion could also be obtained by using a laser exposure to raise the substrate temperature approximately between 1100 and 1350 degrees Celsius for times ranging between 1 microsecond and 1 second.

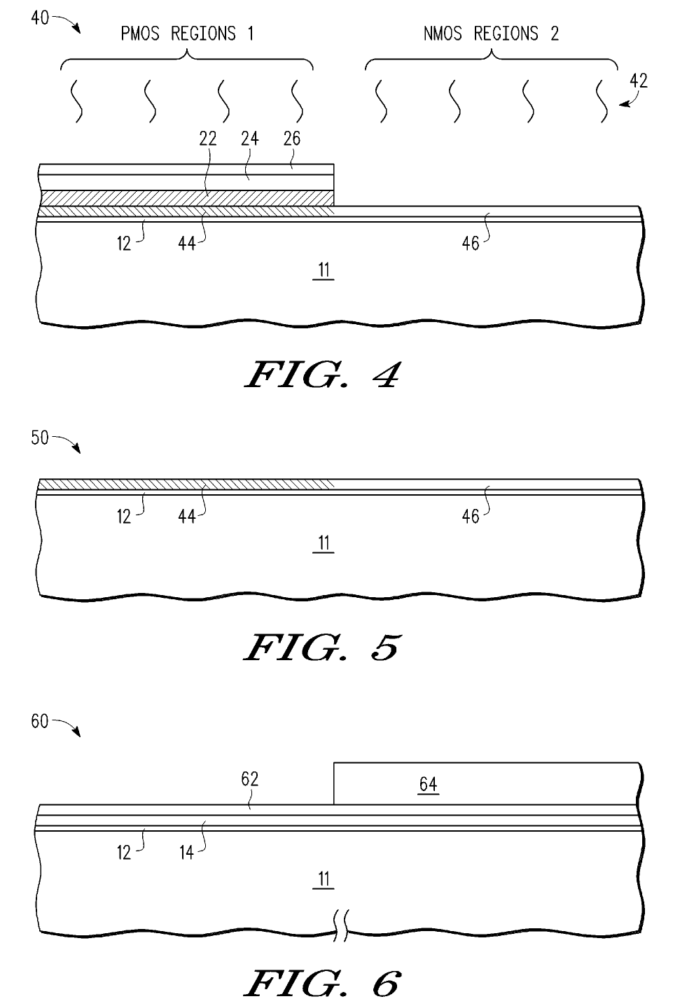

After diffusing nitrogen into the nitrogen-doped metal layer 44, the nitrogen diffusion layers may be removed to facilitate further processing of the gate electrode stack layers. Thus, FIG. 5 illustrates processing of the semiconductor structure 50 subsequent to FIG. 4 after removal of the nitrogen diffusion layer 22, first nitride layer 24, and second nitride cap layer 26. While any desired etch process may be used, in selected embodiments, the remaining layers 22, 24, 26 are stripped using a hard mask removal process that depends on the nature of the hard mask, followed by a piranha or H2O2 clean to selectively remove the nitrogen diffusion layers, thereby exposing the underlying work function-setting metal layers 44, 46. If the hard mask is an oxide layer, dilute hydrofluoric acid may be used to remove the hard mask selective to expose the underlying layers.

As indicated above, other techniques may be used to incorporate or introduce nitrogen into the metal-based electrode layer over the PMOS region to increase the layer's work function. To illustrate one example of these other techniques in which nitrogen is annealed into the metal-based electrode layer 14, reference is now made to FIG. 6 which depicts processing of the semiconductor structure 60 subsequent to FIG. 1 after a patterned photoresist layer 64 is formed over an underlying masking layer 62 formed on the first work function-setting metal layer 14. In particular, a nitride masking layer 62 is formed over the first work function-setting metal layer 14 which will be subsequently etched to serve as an implant or anneal mask to protect the metal-based electrode layer 14 in the NMOS region 2 during a subsequent nitrogen anneal treatment. The nitride masking layer 62 may be formed on the first work function-setting metal layer 14 using any desired deposition or sputtering process, such as CVD, PECVD, PVD, ALD, molecular beam deposition (MBD) or any combination(s) thereof. In a selected embodiment, the nitride masking layer 62 is formed by depositing a layer of silicon nitride having a thickness of between 50 and 150 Angstroms, and more particularly approximately 100 Angstroms, though other nitride materials with different thicknesses may be used. In other embodiments, the masking layer can also be silicon. Once the nitride masking layer 62 is formed, one or more layers of photoresist or other masking layers are applied and patterned using any desired technique to form the patterned mask layer 64.

FIG. 7 illustrates processing of the semiconductor structure 70 subsequent to FIG. 6 after the exposed portions of the masking layer 62 are removed. In particular, with the patterned mask layer 64 in place, the exposed portions of the nitride layer 62 are selectively etched and removed from the PMOS region 1, thereby leaving portions of the nitride layer 62 in the NMOS region 2. The pattern transfer and etching of the mask layer 64 may use one or more etching steps to remove the unprotected portions of the layers 62, including a dry etching process such as reactive-ion etching, ion beam etching, plasma etching or laser etching, a wet etching process wherein a chemical etchant is employed or any combination thereof.

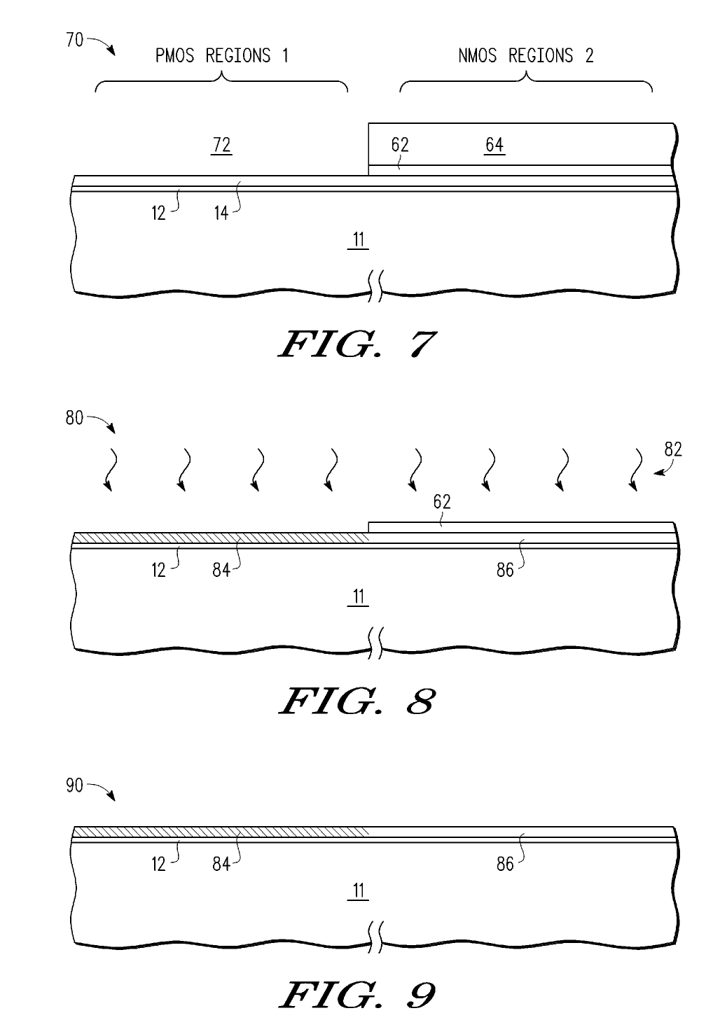

After the mask etch process, the patterned photoresist layer 64 is stripped (e.g., with an ash/piranha process), a nitrogen anneal process may be applied to drive nitrogen into the exposed portion of the first work function-setting metal layer 14 that is not protected by the masking layer 62 so as to increase its work function. This is shown in FIG. 8 which depicts processing of the semiconductor structure 80 subsequent to FIG. 7 while an ammonia (NH₃) anneal process is applied (as indicated by the wave lines 82) to drive nitrogen into the first work function-setting metal layer 84 formed in the PMOS device region 1. At this stage, the nitrogen anneal process incorporates the nitrogen into the first work function-setting metal layer to form the nitrogen-doped metal layer 84 having an adjusted work function. In an example nitrogen anneal process, the time, temperature and other conditions for the nitrogen anneal process are selected to optimize the incorporation of nitrogen into the underlying metal layer for purposes of increasing its work function, such as by using an rapid thermal anneal process which heats the semiconductor device 80 with a temperature ramp up (e.g., 50 degrees per second) to a target temperature of between approximately 600 and 700 degrees Celsius in a nitrogen atmosphere where the temperature is maintained for 5-60 seconds (e.g., a spike anneal drive process), followed by a rapid temperature ramp down. As will be appreciated, other methods may be used to incorporate nitrogen into the metal based electrode layer 84 over the PMOS region 1 to increase the layers work function, such as nitrogen atom or radical exposure from plasmas or implants, etc.

After incorporating nitrogen into the nitrogen-doped metal layer 84, the masking layer 62 may be removed to facilitate further processing of the gate electrode stack layers. Thus, FIG. 9 illustrates processing of the semiconductor structure 90 subsequent to FIG. 8 after removal of the masking layer 62. While any desired etch process may be used, in selected embodiments, the remaining masking layer 62 is stripped using a wet HF etch process, thereby exposing the underlying work function-setting metal layers 84, 86. If the masking layer is silicon, then it can be removed in NH4OH (ammonia hydroxide).

FIG. 10 illustrates processing of the semiconductor structure 100 subsequent to FIGS. 5 or 9 after a silicon-containing cap layer 92 and an anti-reflective coating (ARC) layer 94 are deposited over the underlying work function-setting metal layers to form an unetched gate stack. Since FIG. 10 illustrates the processing subsequent to two both FIGS. 5 and 9, the nitrogen-doped work function-setting metal layers are identified with the reference numbers 44 and 84, while the un-doped work function-setting metal layers are identified with the reference numbers 46 and 86. The silicon-containing layer 92, which is either deposited as a conductive material or subsequently is made to be conductive, is deposited over the underlying work function-setting metal layers 44/84 and 46/86. In a selected embodiment, silicon-containing layer 92 is a polysilicon cap layer or a polysilicon-germanium cap layer formed using CVD, PECVD, PVD, ALD, or any combination(s) thereof to a thickness in the range of approximately 10-150 nanometers, though other materials (e.g., NMOS or PMOS metals) and thicknesses may be used. Silicon-containing layer 92 may also be a doped or undoped amorphous silicon or silicon-germanium layer. An anti-reflective coating (ARC) 94 is subsequently formed over silicon-containing layer 92 to a thickness in the range of approximately 1-20 nm, though other thicknesses may be used. In a selected embodiment, ARC layer 94 is formed by depositing a silicon-rich silicon nitride layer, an organic ARC, a silicon-oxy nitride, or any ARC material which serves an ARC function for the particular lithography process. As will be appreciated, ARC layer 94 may be applied directly to the silicon-containing layer 92 or as part of a multilayer mask on the silicon-containing layer 92.

Once the unetched gate stack is formed, an etched gate stack may be formed using any desired pattern and etching processes to form an etched gate stack over the semiconductor substrate 11, including application and patterning of photoresist directly on the ARC layer 94, though multi-layer masking techniques may also be used. Regardless of which etching process is used, FIG. 11 illustrates processing of the semiconductor structure 110 subsequent to FIG. 4 after the polysilicon cap layer 92 and underlying work function-setting metal layers are selectively etched to form PMOS gate electrodes 101 and NMOS gate electrodes 102. As a preliminary step, a gate mask and etch process is performed to pattern the silicon-containing cap layer 92 and underlying work function-setting metal layers 44/84 and 46/86, resulting in the formation of an etched gate stacks 101, 102 over the substrate 11. The etched PMOS gate stack 101 includes a first nitrogen-doped metal layer 44/84 on the gate dielectric 12 and an overlying cap formed of silicon-containing layer 92, and as a result has an increased work function. The etched NMOS gate stack 102 includes an un-doped metal layer 46/86 on the gate dielectric 12 and an overlying cap formed of silicon-containing layer 92, so that the work function is unchanged. ARC layer 94 may also be initially patterned during the gate stack etch, but it can be fully removed after the gate etch, and thus is not shown in FIG. 11. Because silicon-containing layer 92 serves to protect the metal gates during subsequent etches and cleans, there is no need to keep an ARC layer 94 on top of the gates. This is advantageous in that the ARC layer 94 need not later be separately etched during a contact etch process to form a contact to the gate, and instead can be wet etched. Furthermore, complete removal of the ARC layer 94 enables a more robust silicidation process on top of the gate.

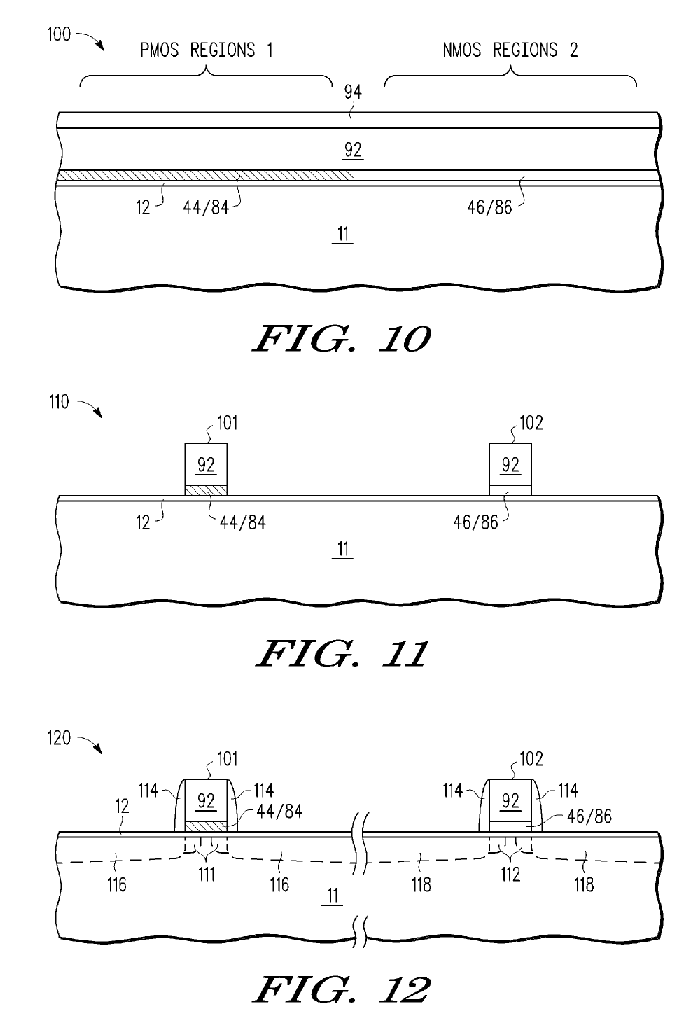

FIG. 12 illustrates processing of the semiconductor structure 120 subsequent to FIG. 11 after source/drain regions are formed around the gate electrode structures 101, 102. While any desired source/drain structure and formation sequence may be used to form the completed transistor structures, the illustrative example forms source/drain regions by implanting halo regions (not shown) and/or shallow extension regions 111, 112 around the etched gate stack structures 101, 102 using conventional implanting processes to implant ions having a predetermined conductivity type. For example, when the gate electrode structures 102 are intended for N channel operation, the extension source/drain regions 112 are implanted with arsenic or phosphorus, though other dopants could be used. When the gate electrode structures 101 are intended for P channel operation, the extension source/drain regions 111 are implanted with boron or another appropriate dopant. During implantation of the source/drain regions 111, 112, each gate electrode structure 101, 102 may optionally include a liner layer (not shown) to protect the gate electrode structures 101, 102. In addition, it will be appreciated that a masking layer (not shown) may be formed over the PMOS circuit area 1 during implantation of the source/drain regions 112 in the NMOS circuit area 2. Likewise, a masking layer (not shown) may be formed over the NMOS circuit area 2 during implantation of the source/drain regions 111 in the PMOS circuit area 1. The source/drain regions 111, 112 may optionally be implanted very near the etched gate stack structures 101, 102 through a thin sidewall spacer or liner oxide (not shown) formed on the etched gate stack structures 101, 102 and exposed substrate 11 prior to implantation. In keeping with conventional processes, the implanted ions are annealed or heated to drive or diffuse the implanted ions into the substrate 11 to form the source and drain regions 111, 112.

As also illustrated in FIG. 12, additional source/drain regions 116, 118 may also be formed in the substrate 11 by implanting ions around sidewall spacers 114 formed on the gate electrode structures 101, 102. The sidewall spacers 114 may be formed by depositing one or more relatively thick dielectric layers (e.g., a 500 Angstrom layer of nitride) over the semiconductor structure 120 using any desired deposition process, and then anisotropically etching the deposited dielectric layer to form the sidewall spacers 114. Depending on the constituent materials and dimensions of the deposited dielectric layer(s), the etching may use one or more anisotropic etch processes to form sidewall spacers 114, including a dry etching process (such as reactive-ion etching, ion beam etching, plasma etching or any combination thereof. In a selected illustrative embodiment, the sidewall spacer processing details may be selected to obtain on each side a minimum predetermined total spacer width (e.g., approximately 200-700 Angstroms). Once the sidewall spacers 114 are in place, additional source/drain regions 116, 118 may be formed by implanting the predetermined ions around the etched gate stack structures 101, 102 and sidewall spacers 114, again using conventional implanting processes. For example, the source/drain regions 116, 118 may be formed as deep source/drain regions using the appropriate dopant for the intended type of device (e.g., NMOS or PMOS). In keeping with conventional processes, the implanted ions are annealed or heated to activate, drive or diffuse the implanted ions into the substrate 11 to form the source/drain regions 116, 118.

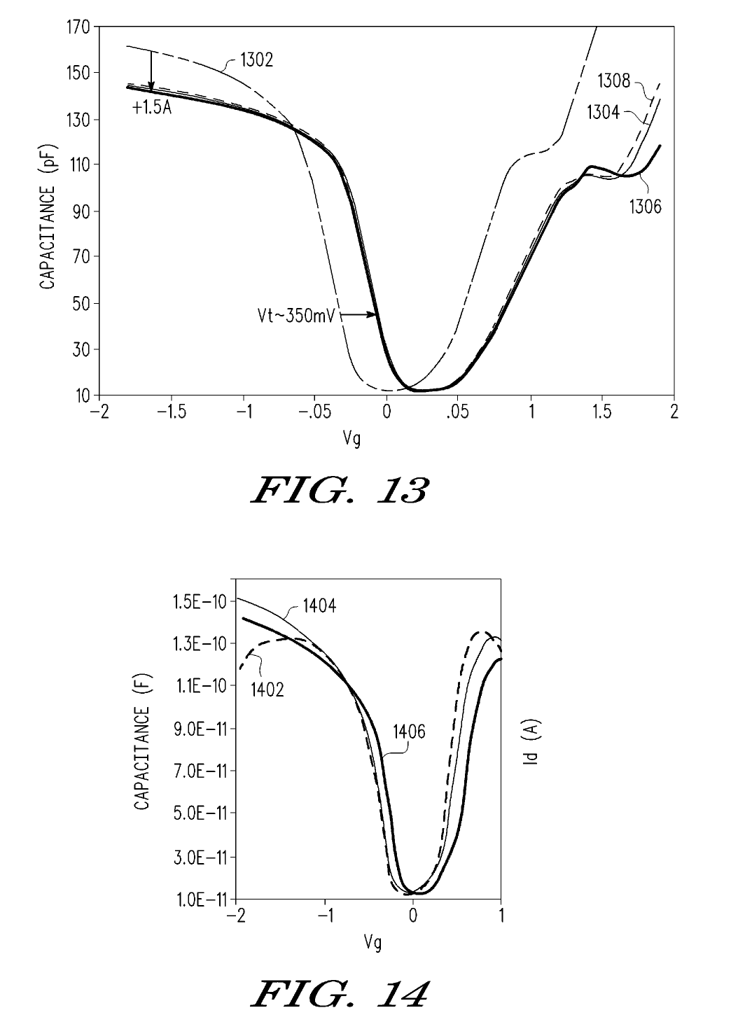

As disclosed herein, a dual metal gate integration process is provided whereby an NMOS metal (i.e., TaC) is selectively capped with a nitrogen-containing layer (e.g., Mo₂N or MoAlN) over the PMOS regions (e.g., using a well photo step to remove the nitrogen-containing layer from the NMOS regions) and then heated with a high temperature anneal. As a result, the effective work function of the TaC layer in the capped PMOS devices is increased between approximately 200-350 mV. To demonstrate the work function shift, reference is made to the simulations shown in the capacitance-voltage plot of FIG. 13 which graphically illustrates the device performance benefits provided in accordance with selected embodiments of the present invention where a nitrogen-containing layer is used as a solid state diffusion source to introduce nitrogen into the underlying TaC base layer. As shown in the plot of FIG. 13, a positive shift of approximately 350 mV in the threshold voltage Vt and an increase of 1.5 A in the Tinv are obtained after the nitrogen is driven into the underlying work function setting metal. To demonstrate the unshifted work function, CV plot line 1302 is provided as a simulation of a control wafer where the PMOS device gate is formed with a TaC layer that is 100 Angstroms thick and no nitrogen doping. In contrast, CV plot line 1304 is provided as a simulation of a PMOS device gate formed with an annealed TaC base layer (100 Angstroms), nitrogen source layer of molybdenum aluminum nitride (MoAlN) (50 Angstroms), and titanium nitride capping layer (70 Angstroms). As the plot line 1304 shows, the CV is shifted to the right as a result of a nitrogen-containing MoAlN layer being on top of the TaC layer. In similar fashion, CV plot line 1306 simulates a PMOS device gate formed with an annealed TaC base layer (100 Angstroms) that is subjected to an H₂O₂ wet chemical treatment, nitrogen source layer of molybdenum aluminum nitride (MoAlN) (50 Angstroms), and titanium nitride capping layer (70 Angstroms). Finally, CV plot line 1308 simulates a PMOS device gate formed with an annealed TaC base layer (100 Angstroms), nitrogen source layer of molybdenum nitride (Mo₂N) (50 Angstroms), and titanium nitride capping layer (70 Angstroms). As the CV plot lines 1304, 1306, and 1308 indicate, the PMOS threshold voltage is shifted or reduced approximately 200-350 mV as a result of a forming a nitrogen-containing layer (either MoAlN or Mo₂N) as a solid state diffusion source on top of the TaC layer. In addition, the timing and temperature of the anneal drive can be adjusted to tune the resulting work function as desired. For example, a first relatively small threshold voltage shift may be obtained by annealing the layers at a first relatively low temperature (e.g., 900 degrees Celsius for 30 seconds). However, by annealing the layers at a higher temperature (e.g., a spike anneal at 1035 degrees Celsius), a larger threshold voltage shift may be obtained. And by retaining a hard mask cap over the nitrogen-containing layers during the anneal, an even larger threshold voltage shift would be expected since the hard mask cap would prevent nitrogen from diffusing away from the TaC base layer.

The work function shift may also be achieved by using the nitrogen anneal process described here, as demonstrated with the simulations shown in the capacitance-voltage plot of FIG. 14. As depicted, CV plot line 1402 is provided as a simulation of the unshifted work function from a PMOS device gate formed with a combination of a TaMgC layer (2.5 Angstroms) and a TaC layer (90 Angstroms) that are not doped with nitrogen. In contrast, CV plot line 1404 is provided as a simulation of a PMOS device gate formed with a combination TaMgC/TaC base layer that is annealed in ammonia (NH₃) at a temperature of 600 degrees Celsius for 60 seconds. As the plot line 1404 shows, the CV is shifted to the right as a result of a nitrogen anneal process driving nitrogen into the TaC layer. In similar fashion, CV plot line 1406 simulates a PMOS device gate formed with a combination TaMgC/TaC base layer that is annealed in ammonia (NH₃) at an elevated temperature of 700 degrees Celsius for 60 seconds. As the CV plot lines 1404 and 1406 indicate, the PMOS threshold voltage is shifted or reduced approximately 200-350 mV as a result of a diffusing nitrogen into the TaC layer with an ammonia anneal process. In addition, the timing and temperature of the nitrogen anneal process can be adjusted to tune the resulting work function as desired. For example, a first relatively small threshold voltage shift may be obtained by performing a nitrogen anneal at a first relatively low temperature (e.g., 600 degrees Celsius for 60 seconds). However, by performing a nitrogen anneal at a higher temperature (e.g., at 700 degrees Celsius for 60 seconds), a larger threshold voltage shift may be obtained.

Possible applications for the gate electrode engineering techniques disclosed herein include forming metal gate electrodes used in transistor devices. In such applications, it will be appreciated that additional processing steps will be used to complete the fabrication of the metal gate electrodes into functional transistor devices. As examples, one or more sacrificial oxide formation, stripping, isolation region formation, extension implant, halo implant, spacer formation, source/drain implant, silicide formation, heat drive or anneal steps, and/or polishing steps may be performed, along with conventional backend processing (not depicted), typically including formation of multiple levels of interconnect that are used to connect the transistors in a desired manner to achieve the desired functionality. In addition, other semiconductor device levels may be formed underneath or above the disclosed semiconductor structures. Thus, the specific sequence of steps used to complete the fabrication of the transistor devices may vary, depending on the process and/or design requirements. While the illustrative embodiments are described with reference to forming a metal gate electrode of a MOSFET transistor device, it will be appreciated that various embodiments of the present invention can be used for any future CMOS technology that utilizes metal gates and high-k dielectrics. Other possible applications of the layer etch techniques disclosed herein include forming metal layers included in non-volatile memory (NVM) transistor devices (such as a nanocluster stack-based NVM devices and floating gates transistor devices), Fin Field Effect Transistors (FinFETs), Double gate Fully Depleted Semiconductor-on-Insulator (FDSOI) transistors or other transistor geometries.

By now it should be appreciated that there is provided herein a method for fabricating a semiconductor structure by forming a gate dielectric layer over a semiconductor substrate, then forming a metal-based electrode base layer (e.g., a thin layer of TaC, HfC, TaSi, ZrC or Hf) over the gate dielectric layer, where the metal-based electrode base layer has a work function that is suitable for an NMOS transistor. Subsequently, nitrogen is selectively introduced into one or more portions of the metal-based electrode base layer where PMOS devices are to be formed to increase the work function of the one or more portions of the metal-based electrode base layer until suitable for a PMOS transistor. After depositing a conductive layer (e.g., polysilicon or metal) over the metal-based electrode base layer, the combined structure is selectively etched to form one or more PMOS gate electrode structures over the PMOS device area and one or more NMOS gate electrode structures over an NMOS device area. A variety of techniques are provided for selectively introducing nitrogen into the metal-based electrode base layer. In selected embodiments, nitrogen is selectively introduced by selectively forming (e.g., depositing, patterning and etching) a nitrogen-containing diffusion source layer (e.g., Mo₂N, MoAlN, RuₓN_{y}, W₂N, etc.) on the metal-based electrode base layer, forming one or more nitride cap layers (e.g., TiN, SiN, etc.) over the nitrogen-containing diffusion source layer, and heating the nitrogen-containing diffusion source layer to drive nitrogen into the metal-based electrode base layer. In selected embodiments, nitrogen is selectively introduced by annealing an exposed portion of the metal-based electrode base layer in nitrogen to increase a work function characteristic of the metal-based electrode base layer. The nitrogen anneal may be performed by exposing the metal-based electrode base layer to nitrogen and/or a nitrogen compound at a temperature of at least approximately 600 degrees Celsius for a predetermined annealing time. Once the conductive layer is deposited, a pattern and etch process may be applied to the conductive layer and the metal-based electrode base layer to form an etched gate stack for use in forming one or more MOS transistors.

In another form, there is provided a method of forming PMOS and NMOS gate electrode structures on a substrate structure. As disclosed, a first metallic layer (e.g., TaC, TiC, HfC, TaSi, ZrC or Hf) is deposited (e.g., by applying a PVD reactive sputtering process) on a gate dielectric layer over the substrate structure. Subsequently, a nitrogen-containing second metallic layer (e.g., Mo₂N, MoAlN, RuₓN_{y}, or W₂N) is selectively formed on the first metallic layer over a PMOS device area, wherein the second metallic layer acts as a nitrogen diffusion source for one or more portions of the first metallic layer located in the PMOS device area. In selected embodiments, the nitrogen-containing second metallic layer is selectively formed by selectively removing part of a deposited nitrogen-containing second metallic layer from the NMOS device area prior to annealing the first and second metallic layers. At this point, one or more nitride cap layers may be formed over the nitrogen-containing second metallic layer. By annealing the first and second metallic layers with the nitride cap layers in place, nitrogen from the second metallic layer diffuses into the first metallic layer, thereby increasing a work function characteristic of the one or more portions of the first metallic layer located in the PMOS device area. After removing the nitrogen-containing second metallic layer (and any nitride cap layer(s)), a conductive layer is deposited over the first metallic layer. Thereafter, the conductive layer, the first metallic layer, and any remaining second metallic layer (that has not been removed) is selectively etched to form one or more PMOS gate electrode structures over the PMOS device area and one or more NMOS gate electrode structures over an NMOS device area.

In yet another form, there is provided a method of forming PMOS and NMOS gate electrode structures on a substrate structure on which a first metallic layer has been deposited on a gate dielectric layer where the first metallic layer has a work function that is suitable for an NMOS transistor. After selectively forming a masking layer on the first metallic layer over an NMOS device area, the first metallic layer over a PMOS device area is exposed. The exposed first metallic layer is then annealed or heated (e.g., at a temperature of at least approximately 600 degrees Celsius) in a nitrogen-containing ambient to increase a work function characteristic of the first metallic layer formed over the PMOS device area. After depositing a conductive layer over the first metallic layer, a selective etch process is applied to selectively etch at least the conductive layer and the first metallic layer to form one or more PMOS gate electrode structures over the PMOS device area and one or more NMOS gate electrode structures over an NMOS device area.

Although the described exemplary embodiments disclosed herein are directed to various semiconductor device structures and methods for making same, the present invention is not necessarily limited to the example embodiments which illustrate inventive aspects of the present invention that are applicable to a wide variety of semiconductor processes and/or devices. Thus, the particular embodiments disclosed above are illustrative only and should not be taken as limitations upon the present invention, as the invention may be modified and practiced in different but equivalent manners apparent to those skilled in the art having the benefit of the teachings herein. For example, the depicted transistor structures may also be formed in a well region (not shown) of the substrate which may be an n-doped well or a p-doped well. Also, the various silicon-based constituent layers may be formed with different conductive materials than those disclosed. In addition, the source and drains and extensions may be p-type or n-type, depending on the polarity of the underlying substrate or well region, in order to form either p-type or n-type semiconductor devices. Moreover, the thickness of the described layers may deviate from the disclosed thickness values, and any specified etch chemistries are provided for illustration purposes only. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method for forming a semiconductor structure, comprising:
providing a substrate;
forming a gate dielectric layer over the substrate;
forming a first metal-based layer over the gate dielectric layer, where the first metal-based layer has a work function that is suitable for an NMOS transistor;
selectively introducing nitrogen into one or more portions of the first metal-based layer where PMOS devices are to be formed to increase the work function of the one or more portions of the first metallic layer until suitable for a PMOS transistor; and
depositing a conductive layer over the first metal-based layer.

2. The method of claim 1 wherein forming a first metal-based layer comprises depositing a thin layer of TaC.

3. The method of claim 1 wherein forming a first metal-based layer comprises depositing a thin layer of TiC, TaC, HfC, TaSi, ZrC or Hf.

4. The method of claim 1, where selectively introducing nitrogen into one or more portions of the first metal-based layer comprises selectively forming a nitrogen-containing diffusion source layer on the one or more portions of the first metal-based layer and heating the nitrogen-containing diffusion source layer to drive nitrogen into the one or more portions of the first metal-based layer.

5. The method of claim 1, where selectively introducing nitrogen into the one or more portions of the first metal-based layer comprises:
forming a nitrogen-containing diffusion source layer on the one or more portions of the first metal-based layer;
forming one or more nitride cap layers over the nitrogen-containing diffusion source layer; and
heating the nitrogen-containing diffusion source layer and one or more nitride cap layers to drive nitrogen into the one or more portions of the first metal-based layer.

6. The method of claim 4, where selectively forming a nitrogen-containing diffusion source layer comprises depositing a layer of molybdenum nitride.

7. The method of claim 4, where selectively forming a nitrogen-containing diffusion source layer comprises depositing a layer of Mo₂N, MoAlN, RuₓN_{y} or W₂N.

8. The method of claim 1, where selectively introducing nitrogen into one or more portions of the first metal-based layer comprises annealing an exposed portion of the first metal-based layer in nitrogen to increase a work function characteristic of the first metal-based layer.

9. The method of claim 1, where selectively introducing nitrogen into one or more portions of the first metal-based layer comprises selectively exposing the first metal-based layer to nitrogen and/or a nitrogen compound at a temperature of at least approximately 600 degrees Celsius.

10. The method of claim 1, where depositing a conductive layer comprises depositing a layer of polysilicon on the first metal-based layer.

11. The method of claim 1 further comprising patterning and etching the conductive layer and first metal-based layer to form an etched gate stack for use in forming one or more NMOS transistors in an NMOS region and one or more PMOS transistors in a PMOS region.

12. A method of forming PMOS and NMOS gate electrode structures on a substrate structure, comprising:
depositing a first metallic layer on a gate dielectric layer over the substrate structure;
selectively forming a nitrogen-containing second metallic layer on the first metallic layer over a PMOS device area, wherein the second metallic layer acts as a nitrogen diffusion source for one or more portions of the first metallic layer located in the PMOS device area;
annealing the first and second metallic layers to diffuse nitrogen from the second metallic layer into the first metallic layer, thereby increasing a work function characteristic of the one or more portions of the first metallic layer located in the PMOS device area;
depositing a conductive layer over the first metallic layer; and
selectively etching at least the conductive layer and the first metallic layer to form one or more PMOS gate electrode structures over the PMOS device area and one or more NMOS gate electrode structures over an NMOS device area.

13. The method of claim 12, where depositing a first metallic layer comprises depositing a thin layer of TiC, TaC, HfC, TaSi, ZrC or Hf.

14. The method of claim 12, where depositing a first metallic layer comprises applying a physical vapor deposition process to reactively sputter TaC to form a TaC layer.

15. The method of claim 12, where selectively forming a nitrogen-containing second metallic layer comprises depositing a layer of Mo₂N, MoAlN, RuₓN_{y}, or W₂N.

16. The method of claim 12, further comprising forming one or more nitride cap layers over the nitrogen-containing second metallic layer prior to annealing the first and second metallic layers.

17. The method of claim 12, where selectively forming a nitrogen-containing second metallic layer comprises:
depositing a nitrogen-containing second metallic layer on the first metallic layer; and
selectively removing the nitrogen-containing second metallic layer from the NMOS device area prior to annealing the first and second metallic layers.

18. The method of claim 12, further comprising removing the nitrogen-containing second metallic layer after annealing the first and second metallic layers and prior to depositing the conductive layer.

19. The method of claim 12, where annealing the first and second metallic layers comprises rapidly heating the first and second metallic layers to a temperature of between approximately 800 to 1350 degrees Celsius.

20. A method of forming PMOS and NMOS gate electrode structures on a substrate structure, comprising:
depositing a first metallic layer on a gate dielectric layer over the substrate structure where the first metallic layer has a work function that is suitable for an NMOS transistor;
selectively forming a masking layer on the first metallic layer over an NMOS device area to expose the first metallic layer over a PMOS device area;
annealing the exposed first metallic layer in a nitrogen-containing ambient to increase a work function characteristic of the first metallic layer formed over the PMOS device area
depositing a conductive layer over the first metallic layer; and
selectively etching at least the conductive layer and the first metallic layer to form one or more PMOS gate electrode structures over the PMOS device area and one or more NMOS gate electrode structures over an NMOS device area.

21. The method of claim 20, where annealing the exposed first metallic layer in a nitrogen-containing ambient comprises heating the exposed first metallic layer in a nitrogen-containing ambient at a temperature of at least approximately 600 degrees Celsius.
